(19) United States
(12) Patent Application Publication
(10) Pub. No.: US 2026/0092670 A1
(43) Pub. Date: Apr. 2, 2026

(54) DISPLAY APPARATUS

(71) Applicant: SAMSUNG ELECTRONICS CO., LTD., Suwon-si (KR)

(72) Inventors: Byeonghwan Choi, Suwon-si (KR); Sanggoo Lee, Suwon-si (KR); Bongjoo Kim, Suwon-si (KR); Euishik Yoon, Suwon-si (KR); Sangin Lee, Suwon-si (KR)

(73) Assignee: SAMSUNG ELECTRONICS CO., LTD., Suwon-si (KR)

(21) Appl. No.: 19/311,489

(22) Filed: Aug. 27, 2025

Related U.S. Application Data
(63) Continuation of application No. PCT/KR2025/012338, filed on Aug. 14, 2025.
(60) Provisional application No. 63/700,141, filed on Sep. 27, 2024.

(30) Foreign Application Priority Data
Dec. 26, 2024 (KR) 10-2024-0197756

(51) Int. Cl. F16M 11/10; H05K 5/02; H05K 5/03

(52) U.S. Cl. CPC F16M 11/10; H05K 5/0234; H05K 5/03; F16M 2200/022; F16M 2200/08

(57) ABSTRACT

A display apparatus may include: a display including a display panel and a chassis supporting the display panel; a stand configured to support the display; and a support device between the display and the stand, wherein the support device includes: a first support member including a center hole; a fastening shaft including a body portion including a thread on an outer circumferential surface of the body portion, and the fastening shaft further including a head portion having a larger diameter than a diameter of the body portion, wherein the fastening shaft is configured to connect the first support member to the stand by the body portion extending through the center hole and screw-connecting to the stand; a second support member connected to the chassis and the first support member, wherein the first support member is configured to rotate with respect to the stand about the fastening shaft, and wherein the second support member is configured to move in an up-and-down direction with respect to the first support member.

### CROSS-REFERENCE TO RELATED APPLICATIONS

This application is a by-pass continuation of International Application No. PCT/KR2025/012338, filed on Aug. 14, 2025, which claims priority from Korean Patent Application No. 10-2024-0197756, filed in the Korean Intellectual Property Office on Dec. 26, 2024, and U.S. Provisional Application No. 63/700,141, filed in the United States Patent and Trademark Office on Sep. 27, 2024, the disclosures of which are incorporated herein by reference in their entireties.

### BACKGROUND

### 1. Field

The disclosure relates to a display apparatus having an improved structure.

### 2. Description of Background Art

A display apparatus is a type of output device that converts acquired or stored electrical information into visual information and displays such information to a user.

A display may include a self-emissive display panel, such as an organic light-emitting diode (OLED), or a non-emissive display panel, such as a liquid crystal display (LCD).

In addition, the display may include a chassis that supports a display panel and a rear cover that covers the rear of the chassis.

A display apparatus may include the display mentioned above and a stand that supports the display.

### SUMMARY

According to an embodiment of the present disclosure, a display apparatus including a stand may be provided.

According to an embodiment of the present disclosure, a display apparatus including a stand with an improved structure may be provided.

According to an embodiment of the present disclosure, a display apparatus including a stand capable of leveling a display panel may be provided.

According to an embodiment of the present disclosure, a display apparatus including a stand that may increase productivity by simplifying the structure may be provided.

Technical aspects achieved by embodiments of the present disclosure are not limited to the technical aspects mentioned above, and other technical aspects of embodiments of the present disclosure not mentioned will be clearly understood by those skilled in the art from the description below.

According to some embodiments of the present disclosure, a display apparatus may include: a display including a display panel and a chassis supporting the display panel; a stand configured to support the display; and a support device between the display and the stand, wherein the support device includes: a first support member including a center hole; a fastening shaft including a body portion including a thread on an outer circumferential surface of the body portion, and the fastening shaft further including a head portion having a larger diameter than a diameter of the body portion, wherein the fastening shaft is configured to connect the first support member to the stand by the body portion extending through the center hole and screw-connecting to the stand; a second support member connected to the chassis and the first support member, wherein the first support member is configured to rotate with respect to the stand about the fastening shaft, and wherein the second support member is configured to move in an up-and-down direction with respect to the first support member.

According to some embodiments of the present disclosure, a system may include: a display including a display panel and a chassis supporting the display panel; a stand configured to support the display; and a support device configured to be between the display and the stand, wherein the support device includes: a first support member including a center hole; a fastening shaft configured to connect the first support member to the stand while the fastening shaft extends through the center hole; and a second support member configured to be connected to the chassis and the first support member, wherein the first support member is configured to rotate with respect to the stand about the fastening shaft, and wherein the second support member is configured to move in an up-and-down direction with respect to the first support member.

According to some embodiments of the present disclosure, a support device of a display apparatus may include: a first support member including a center hole; a fastening shaft including a body portion including a thread on an outer circumferential surface of the body portion, and the fastening shaft further including a head having a larger diameter than a diameter of the body portion, wherein the fastening shaft is configured to connect the first support member to a stand of the display apparatus by the body portion extending through the center hole and screw-connecting to the stand; and a second support member configured to be connected to the first support member and a display of the display apparatus, wherein the first support member is configured to rotate with respect to the stand about the fastening shaft, and wherein the second support member is configured to move in an up-and-down direction with respect to the first support member.

According to various embodiments of the present disclosure, the stand may be formed by injection molding using a resin material. Such a configuration may cause the manufacturing cost and material cost of the display apparatus to be relatively reduced.

According to various embodiments of the present disclosure, the display panel may be leveled by including the stand with an improved structure.

According to various embodiments of the present disclosure, productivity may be increased by simplifying the stand structure.

According to various embodiments of the present disclosure, by minimizing pressed parts, costs may be reduced and high serviceability may be ensured.

The effects obtained by embodiments of the present disclosure are not limited to those mentioned above, and other effects obtained by embodiments of the present disclosure not mentioned will be apparent to a person skilled in the art to which the present disclosure belongs from the following description.

### BRIEF DESCRIPTION OF DRAWINGS

FIG. 1 is a view illustrating a display apparatus according to an embodiment.

FIG. 2 is a view illustrating the display apparatus according to an embodiment, viewed from another direction.

FIG. 3 is a view illustrating a state in which a display and a stand are separated, according to an embodiment.

FIG. 4 is a view illustrating a state in which the display and the stand are separated according to an embodiment, viewed from another direction.

FIG. 5 is a view illustrating the stand and a support device according to an embodiment.

FIG. 6 is a view illustrating an exploded state of the support device of the stand shown in FIG. 5.

FIG. 7 is a view illustrating an exploded state of some configurations of the support device shown in FIG. 6.

FIG. 8 is a cross-sectional view taken along a line A-A′ of FIG. 5, illustrating a cross-section of some configurations of the support device according to an embodiment.

FIG. 9 is a view illustrating an exploded state of some configurations of the support device shown in FIG. 7.

FIG. 10 is a view illustrating an exploded state of some configurations of the support device shown in FIG. 9, viewed from another direction.

FIG. 11 is a view illustrating a portion of a first support member of the support device according to an embodiment.

FIG. 12 is a view illustrating a portion of the stand coupled to the first support member according to an embodiment.

FIG. 13 is a view illustrating a coupled state of the support device and the stand according to an embodiment.

FIG. 14 is a view illustrating a rotational state of the first support member with respect to the stand according to an embodiment.

FIG. 15 is a cross-sectional view taken along a line B-B′ of FIG. 5, illustrating a cross-section of some configurations of the stand and the support device according to an embodiment.

FIG. 16 is a view illustrating a state in which the first support member is coupled to the stand according to an embodiment.

FIG. 17 is a cross-sectional view illustrating the support device coupled to the stand according to an embodiment.

### DETAILED DESCRIPTION

Various example embodiments of the present disclosure and terms used herein are not intended to limit the present disclosure to specific embodiments, and the present disclosure should be understood to include various modifications, equivalents, and substitutions of the corresponding embodiments.

In describing of the drawings, similar reference numerals may be used for similar or related elements.

The singular form of a noun corresponding to an item may include one or more of the items unless clearly indicated otherwise in a related context.

In the disclosure, phrases, such as “A or B,” “at least one of A and B,” “at least one of A or B,” “A, B or C,” “at least one of A, B and C,” and “at least one of A, B, or C” may include any one or all possible combinations of the items listed together in the corresponding phrase among the phrases.

As used herein, the term “and/or” includes any and all combinations of one or more of the associated listed items.

Terms such as “first,” “second,” “primary,” or “secondary” may be used simply to distinguish an element from other elements, without limiting the element in other aspects (e.g., importance or order).

When an element (e.g., a first element) is referred to as being “(functionally or communicatively) coupled” or “connected” to another element (e.g., a second element), the first element may be connected to the second element, directly (e.g., wired), wirelessly, or through a third element.

It will be understood that when the terms “includes,” “comprises,” “including,” and/or “comprising” are used in the disclosure, they specify the presence of the specified features, figures, steps, operations, components, members, or combinations thereof, but do not preclude the presence or addition of one or more other features, figures, steps, operations, components, members, or combinations thereof.

When a given element is referred to as being “connected to,” “coupled to,” “supported by,” or “in contact with” another element, it is to be understood that it may be directly or indirectly connected to, coupled to, supported by, or in contact with the other element. When a given element is indirectly connected to, coupled to, supported by, or in contact with another element, it is to be understood that it may be connected to, coupled to, supported by, or in contact with the other element through a third element.

It will also be understood that when an element is referred to as being “on” another element, it may be directly on the other element or intervening elements may also be present.

In addition, the terms “portion,” “unit,” “part,” “module,” and “member” may be implemented in hardware or software. Depending on the embodiments, a plurality of “portions,” “units,” “parts,” “modules,” and “members” may be implemented as a single element, or a single “portion,” “unit,” “part,” “module,” or “member” may include a plurality of elements.

Furthermore, the terms such as “portion,” “unit,” “part,” “module,” “member,” or the like may refer to a unit that processes at least one function or operation. For example, these terms may refer to at least one hardware such as a field-programmable gate array (FPGA) or an application specific integrated circuit (ASIC), or at least one software stored in memory.

The reference numerals attached to each step may be used to identify each step, and these reference numerals do not indicate the order between each step. Each step may be performed in a different order from the stated order unless a specific order is clearly required in the context.

Terms used in the following description, such as “front,” “rear,” “left,” “right,” “up,” “down,” or the like, may be defined based on the drawings; however, the shape and position of each component are not limited by these terms. For example, a front side may be defined as a +X side, and a rear side may be defined as the −X side. For example, based on the drawings, a left side may be defined as a +Y side, and a right side may be defined as the −Y side. For example, based on the drawings, an upper side may be defined as a +Z side, and a lower side may be defined as the −Z side.

Hereinafter, various non-limiting example embodiments of the present disclosure will be described in detail with reference to the accompanying drawings.

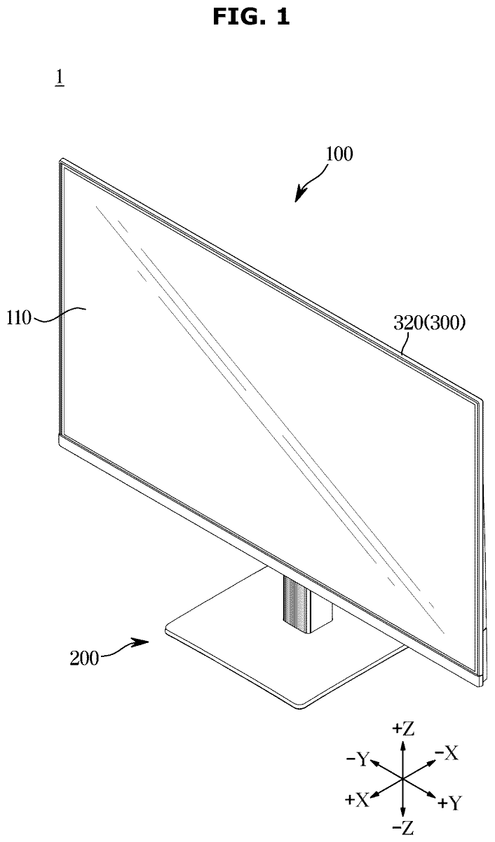

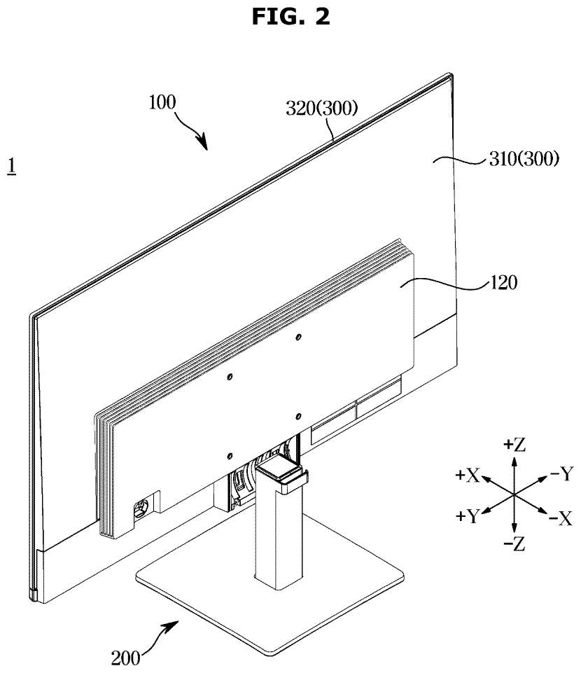

FIG. 1 is a view illustrating a display apparatus according to an embodiment. FIG. 2 is a view illustrating the display apparatus according to an embodiment, viewed from another direction.

Referring to FIGS. 1 and 2, a display apparatus 1 may include a display 100 and a stand 200 configured to support the display 100. The display apparatus 1 may be a device that displays information, material, data, or the like in the form of text, shapes, graphs, images, or the like, and may include a television, a monitor, or the like.

The display 100 may include a display panel 110. The display panel 110 may be configured to display a screen. The display panel 110 may include a self-emissive display panel, such as an organic light-emitting diode (OLED), or a non-emissive display panel, such as a liquid crystal display (LCD). There is no particular limitation on the type of the display panel 110.

The display 100 may include a chassis 300. The chassis 300 may support the display panel 110. The chassis 300 may accommodate the display panel 110. The chassis 300 may form an exterior of the display 100.

The chassis 300 may include a rear chassis 310. The rear chassis 310 may be arranged on a rear side of the display panel 110. The rear chassis 310 may cover the rear side of the display panel 110.

The chassis 300 may include a front chassis 320. The front chassis 320 may be arranged along an edge of the display panel 110. The front chassis 320 may cover the edge of the display panel 110. The front chassis 320 may be arranged on a front side of the rear chassis 310.

The display 100 may include a rear cover 120. The rear cover 120 may cover a rear side of the chassis 300. The rear cover 120 may be coupled to the rear side of the chassis 300. In particular, the rear cover 120 may cover a rear side of the rear chassis 310. In particular, the rear cover 120 may be coupled to the rear side of the rear chassis 310.

According to some embodiments, the display 100 may include a plurality of optical sheets, a backlight unit that emits light, a control module that controls internal configurations of the display panel 110, and the like. According to some embodiments, the display 100 may alternatively or additionally include various other components.

The display apparatus 1 may include the stand 200. The stand 200 may be configured to support the display 100.

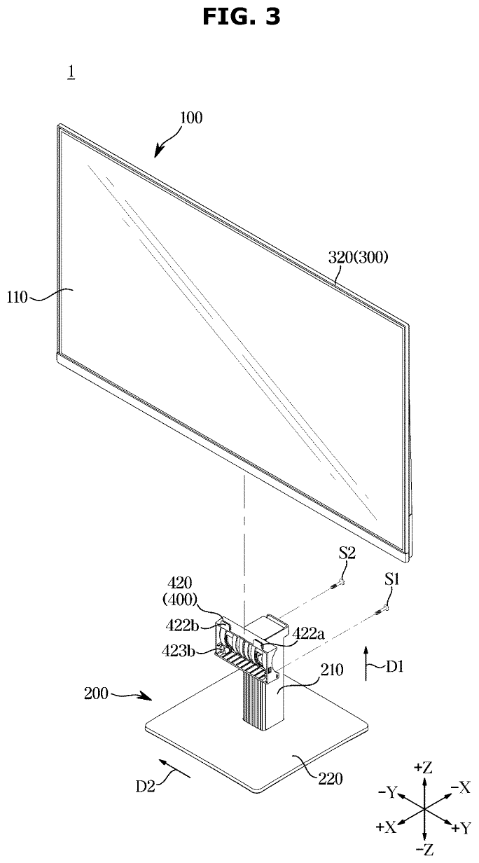

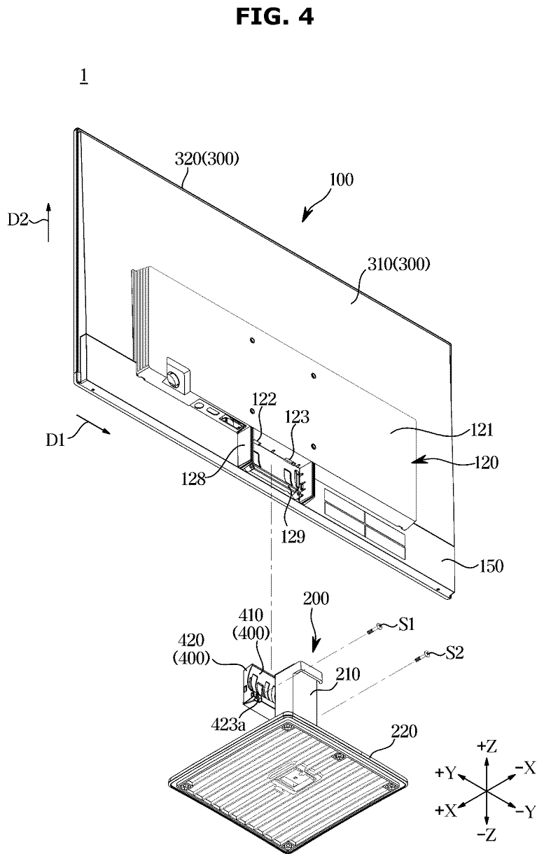

FIG. 3 is a view illustrating a state in which a display and a stand are separated according to an embodiment. FIG. 4 is a view illustrating a state in which the display and the stand are separated according to an embodiment, viewed from another direction.

Referring to FIGS. 3 and 4, the stand 200 may be detachably coupled to the display 100. In particular, the stand 200 may be detachably coupled to a lower rear end of the display 100. With such a configuration, the display 100 may be arranged to be spaced apart from a bottom on which the display apparatus 1 is mounted.

The stand 200 may be detachably coupled to the display 100 by means of a support device 400 (e.g., a supporter). The display 100 may be provided with the support device 400 between the stand 200 and the display 100. When the stand 200 is coupled to the display 100, the support device 400 may be coupled to the rear cover 120. When the stand 200 is coupled to the display 100, the support device 400 may be seated on a stand seating portion 129 provided between two guide walls 128 formed on the lower rear end of the rear cover 120. A detailed description of the support device 400 will be provided below.

The stand 200 may include a stand leg 210. The stand leg 210 may be coupled to the support device 400. The stand leg 210 may be coupled with the support device 400 to couple the display 100 to the stand 200. The stand leg 210 may extend along a first direction D1. In particular, the stand leg 210 may extend in an up-and-down direction (e.g., Z-axis direction).

The stand 200 may include a stand base 220. The stand base 220 may be coupled to the stand leg 210. The stand base 220 may be configured to support the stand leg 210. The stand base 220 may be provided below the stand leg 210. The stand base 220 may be configured to support the stand leg 210 and the support device 400 coupled to the stand leg 210.

The support device 400 may be disposed between the stand 200 and the display 100, such that the display 100 is supportable with respect to the stand 200.

The stand 200 may be coupled to the display 100 by the support device 400. At least a portion of the support device 400 may be coupled to the display 100. For example, the support device 400 may include a first insertion protrusion 422a provided to be coupled to the display 100. For example, the first insertion protrusion 422a may be arranged to protrude from a portion of the support device 400. For example, the first insertion protrusion 422a may be arranged on an upper side of the support device 400. For example, the first insertion protrusion 422a may be arranged to protrude upwardly from a portion of the support device 400.

The first insertion protrusion 422a may be arranged to protrude from some component(s) of the support device 400. For example, the first insertion protrusion 422a may be arranged to protrude from a second support member 420. For example, the first insertion protrusion 422a may be arranged on an upper side of the second support member 420. For example, the first insertion protrusion 422a may be arranged to protrude upwardly from the second support member 420.

The support device 400 may include a second insertion protrusion 422b arranged to be coupled to the display 100. For example, the second insertion protrusion 422b may be arranged to protrude from a portion of the support device 400. For example, the second insertion protrusion 422b may be arranged on an upper side of the support device 400. For example, the second insertion protrusion 422b may be arranged to protrude upwardly from a portion of the support device 400.

The second insertion protrusion 422b may be arranged to protrude from some component(s) of the support device 400. For example, the second insertion protrusion 422b may be arranged to protrude from the second support member 420. For example, the second insertion protrusion 422b may be arranged on an upper side of the second support member 420. For example, the second insertion protrusion 422b may be arranged to protrude upwardly from the second support member 420.

The second insertion protrusion 422b may be arranged to be spaced apart from the first insertion protrusion 422a in a second direction D2 intersecting the first direction D1. In other words, the first insertion protrusion 422a and the second insertion protrusion 422b may be arranged side by side in the second direction D2. In particular, the second insertion protrusion 422b may be arranged to the right (e.g., −Y direction) of the first insertion protrusion 422a.

When the stand 200 is coupled to the display 100, the first insertion protrusion 422a of the support device 400 coupled to the stand 200 may be inserted into a first through-hole 122 and a first insertion hole 341b, which will be described below. When the stand 200 is coupled to the display 100, the second insertion protrusion 422b of the support device 400 coupled to the stand 200 may be inserted into a second through-hole 123 and a second insertion hole 342b, which will be described below. Further details will be provided below.

Although the support device 400 is shown in the drawings as including a total of two insertion protrusions 422, there is no particular limitation on the number of insertion protrusions. For example, the number of the insertion protrusions may be one, or three or more.

The support device 400 may include a first fastening member through-hole 423a. A first fastening member S1, which will be described below, may be inserted into the first fastening member through-hole 423a. The first fastening member through-hole 423a may be arranged in a lower portion of the support device 400. However, there is no particular limitation on the location of the first fastening member through-hole 423a.

The support device 400 may include a second fastening member through-hole 423b. A second fastening member S2, which will be described below, may be inserted into the second fastening member through-hole 423b. The second fastening member through-hole 423b may be provided in the lower portion of the support device 400. However, there is no particular limitation on the locations of the second fastening member through-hole 423b.

The second fastening member through-hole 423b may be arranged to be spaced apart from the first fastening member through-hole 423a in the second direction D2. In other words, the first fastening member through-hole 423a and the second fastening member through-hole 423b may be arranged side by side in the second direction D2. In particular, the second fastening member through-hole 423b may be arranged to the right (e.g., −Y direction) of the first fastening member through-hole 423a.

The support device 400 and the stand 200 coupled to the support device 400 may be secured to the display 100, by inserting and fastening the first fastening member S1 into the first fastening member through-hole 423a and a first fastening member insertion groove arranged in the display 100, and by inserting and fastening the second fastening member S2 into the second fastening member through-hole 252 and a second fastening member insertion groove arranged in the display 100. Further details will be provided below.

Although the stand 200 is shown in the drawings as including a total of two fastening member through-holes 423, there is no particular limitation on the number of fastening member through-holes. For example, one fastening member through-hole may be provided, or three or more fastening member through-holes may be provided.

The display 100 may include the chassis 300. The chassis 300 may include the rear chassis 310 and the front chassis 320.

The chassis 300 may include a base plate. The base plate may be arranged on the rear side of the display panel 110. The base plate may be arranged on an inner side of the rear chassis 310.

According to some embodiments, the base plate may be provided with the first fastening member insertion groove for inserting and fastening the first fastening member S1 that passes through the first fastening member through-hole 423a of the support device 400 and may be coupled thereto. The base plate may be provided with the second fastening member insertion groove for inserting and fastening the second fastening member S2 that passes through the second fastening member through-hole 423b of the support device 400 and may be coupled thereto.

The rear chassis 310, the front chassis 320, and the base plate of the display 100 may be integrally formed. In particular, the rear chassis 310, the front chassis 320, and the base plate may be formed by injection molding. In other words, the chassis 300 may be formed by injection molding. The rear chassis 310, the front chassis 320, and the base plate may include a resin material. In other words, the chassis 300 may include a resin material.

According to embodiments of the present disclosure, the chassis 300 may be formed by injection molding by using a resin material. With such a configuration, the manufacturing cost and material cost of the display apparatus 1 may be relatively reduced.

The display 100 may include the rear cover 120. The rear cover 120 may be coupled to the rear side of the chassis 300 to cover the rear side of the chassis 300. In particular, the rear cover 120 may be coupled to a rear side of the base plate to cover the rear side of the chassis 300.

The rear cover 120 may include a rear cover body 121. The rear cover body 121 may form an overall exterior of the rear cover 120.

The rear cover 120 may include the first through-hole 122. The first through-hole 122 may be provided for insertion of the first insertion protrusion 422a. The first through-hole 122 may be arranged on a lower side of the rear cover 120. In particular, the first through-hole 122 may be arranged on an upper side of the stand seating portion 129.

The rear cover 120 may include the second through-hole 123. The second through-hole 123 may be provided for insertion of the second insertion protrusion 422b. The second through-hole 123 may be provided on the lower side of the rear cover 120. In particular, the second through-hole 123 may be arranged on the upper side of the stand seating portion 129.

The second through-hole 123 may be arranged to be spaced apart from the first through-hole 122 in the second direction D2. In other words, the first through-hole 122 and the second through-hole 123 may be arranged side by side in the second direction D2. In particular, the second through-hole 123 may be arranged to the right (e.g., −Y direction) of the first through-hole 122.

When the stand 200 is coupled to the display 100, the first insertion protrusion 422a may be inserted into the first through-hole 122. When the stand 200 is coupled to the display 100, the second insertion protrusion 242 may be inserted into the second through-hole 123.

The support device 400 and the stand 200 coupled to the support device 400 may be secured to the display 100 by inserting and fastening the first fastening member S1 passing through the first fastening member through-hole 423a of the support device 400 into the first fastening member insertion groove of the display 100.

The support device 400 and the stand 200 coupled to the support device 400 may be secured to the display 100 by inserting and fastening the second fastening member S1 passing through the second fastening member through-hole 423b of the support device 400 into the second fastening member insertion groove of the display 100. With such a configuration, the stand 200 may be secured to the display 100 via the support device 400.

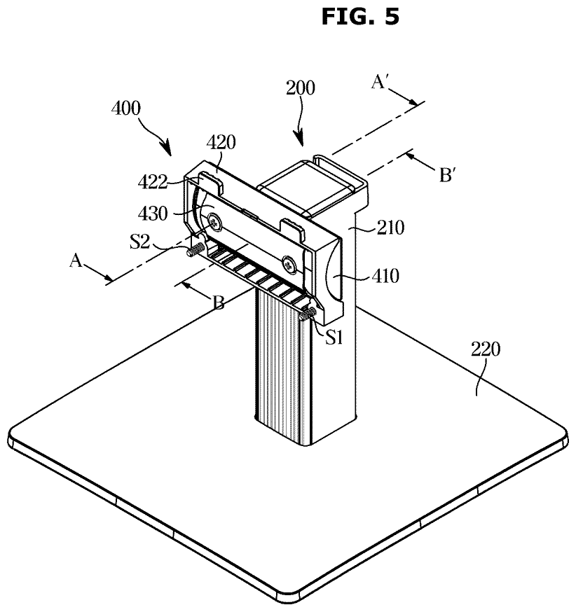

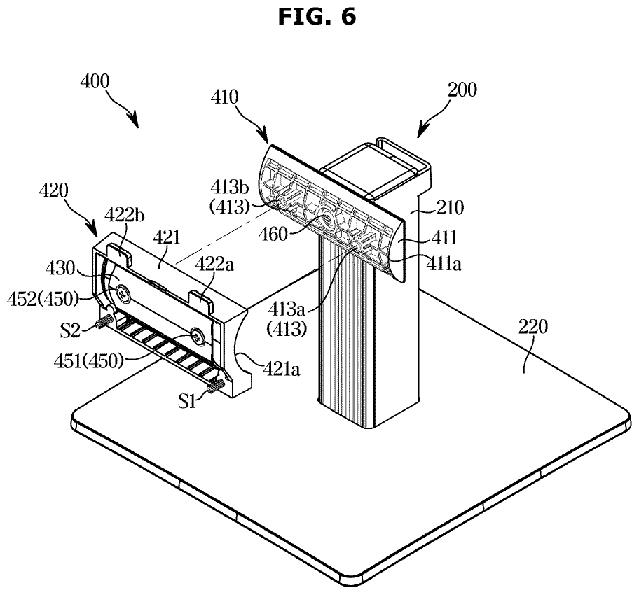

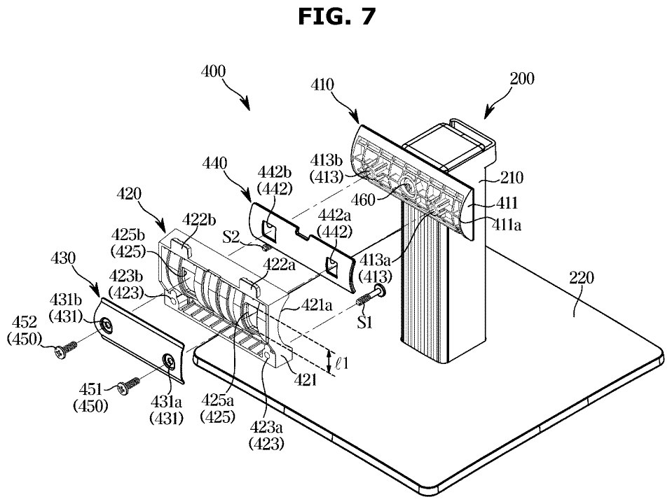

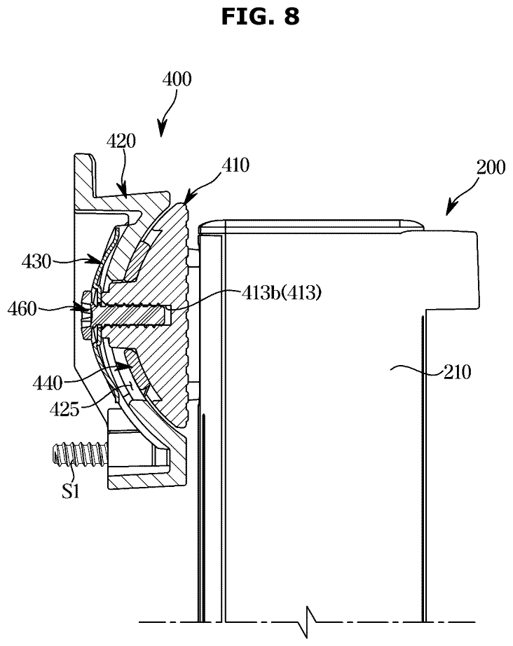

FIG. 5 is a view illustrating the stand and the support device according to an embodiment. FIG. 6 is a view illustrating an exploded state of the support device of the stand shown in FIG. 5. FIG. 7 is a view illustrating an exploded state of some configurations of the support device shown in FIG. 6. FIG. 8 is a cross-sectional view taken along a line A-A′ of FIG. 5, illustrating a cross-section of some configurations of the support device according to an embodiment.

Referring to FIGS. 5 to 8, the support device 400 may be disposed between the display 100 and the stand 200.

The support device 400 may be disposed between the display 100 and the stand 200, and configured to movably support the display 100. For example, the support device 400 may rotatably support the display 100 with respect to the stand 200. For example, the support device 400 may movably support the display 100 in the up-and-down direction with respect to the stand 200.

The support device 400 may be coupled to the stand 200. For example, the support device 400 may be coupled to the stand leg 210 of the stand 200. For example, at least a portion of the support device 400 may be movably coupled to the stand leg 210. For example, at least a portion of the support device 400 may be movably coupled to the stand 200 by a fastening shaft 460. For example, at least a portion of the support device 400 may be movably coupled to the stand leg 210 by the fastening shaft 460.

The support device 400 may include a first support member 410. The first support member 410 may be coupled to the stand 200 by the fastening shaft 460. The first support member 410 may be provided by injection molding. The first support member 410 may be arranged to be coupled to the stand 200. The first support member 410 may be arranged to be movably coupled to the stand 200. The first support member 410 may be movably coupled to the stand 200 by the fastening shaft 460, which will be described below. For example, the first support member 410 may include a center hole 412 (see FIG. 8). For example, the first support member 410 may be formed with the center hole 412 for coupling of the fastening shaft 460. For example, the first support member 410 may be coupled to the stand 200 by the fastening shaft 460 passing through the center hole 412.

The first support member 410 may include a first support member body 411. The first support member 410 may include a round portion 411a having a front surface protruding forward. A front surface of the first support member body 411 may include the round portion 411a. The round portion 411a may be arranged to protrude forwardly from the first support member body 411. For example, the front surface of the first support member body 411 may include the round portion 411a in a spherical shape.

The support device 400 may include the fastening shaft 460 configured to couple the first support member 410 to the stand 200. A detailed description of the fastening shaft 460 and the first support member 410 will be provided below.

The support device 400 may include the second support member 420 coupled to the first support member 410. The support device 400 may include the second support member 420 that is secured to the chassis 300 and coupled to the first support member 410. The second support member 420 may be secured to the display 100 via the chassis 300. The second support member 420 may be coupled to the first support member 410 and may be movably arranged in the up-and-down direction with respect to the first support member 410. The second support member 420 may be formed by injection molding.

The first support member 410 and the second support member 420 constituting the support device 400 may be formed by injection molding by using a resin material, and due to such a configuration, the manufacturing cost and material cost of the display apparatus 1 may be relatively reduced.

The second support member 420 may be arranged in front of the first support member 410. The second support member 420 may be movably arranged with respect to the first support member 410. For example, the second support member 420 may be movably arranged relative to the first support member 410. For example, the second support member 420 may be movably arranged in the up-and-down direction with respect to the first support member 410.

The second support member 420 may be movably arranged in the up-and-down direction with respect to the first support member 410. The second support member 420 may be shaped to correspond to the front surface of the first support member 410. At least a portion of the second support member 420 may be shaped to correspond to the round portion 411a of the first support member 410.

The second support member 420 may include a second support member body 421. The second support member 420 may include a curved portion 421a having a rear surface recessed forward. The rear surface of the second support member body 421 may include the curved portion 421a. The curved portion 421a may be arranged on the rear surface of the second support member body 421. For example, the rear surface of the second support member body 421 may be arranged to be recessed forward. For example, the rear surface of the second support member body 421 may include a curved portion 421a that is spherical and recessed forward.

The second support member body 421 may include the curved portion 421a corresponding to the round portion 411a in order to be movable in the up-and-down direction of the first support member 410. The rear surface of the second support member body 421 may include the curved portion 421a. The rear surface of the second support member body 421 may include the curved portion 421a corresponding to the round portion 411a in order to be movable in the up-and-down direction with respect to the first support member 410.

The first support member 410 and the second support member 420 may be arranged to be contactable with each other. The front surface of the first support member 410 and the rear surface of the second support member 420 may be arranged to be contactable with each other. The first support member 410 and the second support member 420 may be arranged to be contactable with each other to generate a frictional force. The front surface of the first support member 410 and the rear surface of the second support member 420 may be arranged to be contactable with each other to generate a frictional force.

The first support member body 411 and the second support member body 421 may be arranged to be contactable with each other. The front surface of the first support member body 411 and the rear surface of the second support member body 421 may be arranged to be contactable with each other. The first support member body 411 and the second support member body 421 may be arranged to be contactable with each other to generate a frictional force. The front surface of the first support member body 411 and the rear surface of the second support member body 421 may be arranged to be contactable with each other to generate a frictional force.

The round portion 411a of the first support member 410 and the curved portion 421a of the second support member 420 may be arranged to be contactable with each other. The round portion 411a of the first support member 410 and the curved portion 421a of the second support member 420 may be arranged to be contactable with each other to generate a frictional force.

The second support member 420 may be arranged to be movable in the up-and-down direction with respect to the first support member 410 in front of the first support member 410. The display 100 coupled to the second support member 420 may be arranged to be movable in the up-and-down direction with respect to the first support member 410.

The support device 400 may include a cover 430. The support device 400 may include the cover 430 configured to support the second support member 420. The support device 400 may include the cover 430 arranged on one side of the second support member 420. The support device 400 may include the cover 430 arranged to contact one surface of the second support member 420.

The cover 430 may be arranged on a front side of the second support member 420. The cover 430 may be configured to secure the second support member 420 to the first support member 410. The cover 430 may be arranged corresponding to a front surface of the second support member 420. The cover 430 may be configured to contact the front surface of the second support member body 421. The cover 430 may be configured to contact the front surface of the second support member body 421. The cover 430 may be provided in an approximately plate shape. The cover 430 may include a fixing member 450 configured to secure the cover 430 to the first support member 410. The cover 430 may be provided with a fixing member through-hole 431 formed through which the fixing member 450 may be coupled. Two fixing member through-holes 431 may be spaced apart from each other. For example, the fixing member through-holes 431 may include a first fixing member through-hole 431a formed on one side of the cover 430. For example, the fixing member through-holes 431 may include a second fixing member through-hole 431b formed on the other side of the cover 430. For example, the first fixing member through-hole 431a and the second fixing member through-hole 431b may be spaced apart from each other.

The fixing member 450 may be configured to pass through the cover 430 and be secured to the first support member 410. The fixing member 450 may pass through the cover 430 and be secured to the first support member 410, thereby allowing the second support member 420 between the cover 430 and the first support member 410 to be movably coupled in the up-and-down direction with respect to the first support member 410.

The second support member 420 may be provided with a through-hole 425 through which the fixing member 450 may pass. The through-hole 425 may be arranged in the second support member body 421. The through-hole 425 may be provided corresponding to the fixing member through-hole 431 of the cover 430. Two through-holes 425 of the second support member 420 may be provided to correspond to the two fixing member through-holes 431 of the cover 430. The through-hole 425 may be provided corresponding to the first fixing member through-hole 431a and the second fixing member through-hole 431b, respectively. The through-hole 425 may be elongated in the up-and-down direction to allow movement up and down around the fixing member 450 passing through the second support member 420. The through-hole 425 may be formed with a first length l1 in the up-and-down direction. The through-holes 425 may include a first through-hole 425a formed at a position corresponding to the first fixing member through-hole 431a. The through-hole 425 may include a second through-hole 425b formed at a position corresponding to the second fixing member through-hole 431b. The first through-hole 425amay be formed with the first length l1 in the up-and-down direction of the second support member 420. The second through-hole 425b may be formed with the first length l1 in the up-and-down direction of the second support member 420.

The fixing member 450 may pass through the through-hole 425 of the second support member 420 and be secured to the first support member 410. The second support member 420 may be moved in the up-and-down direction with respect to the first support member 410 by the first length l1 of the through-hole 425. Since the fixing member 450 passes through the through-hole 425 of the second support member 420 while being inserted into the fixing member through-hole 431 of the cover 430 and is secured to the first support member 410, the second support member 420 between the cover 430 and the first support member 410 may be moved in the up-and-down direction about the fixing member 450 within the first length l1 of the through-hole 425.

For example, a first fastening member 451 may be inserted into the first fixing member through-hole 431a of the cover 430, pass through the first through-hole 425a of the second support member 420, and be secured to the first support member 410. Since the first fastening member 451 passes through the first through-hole 425a of the second support member 420 while being inserted into the first fixing member through-hole 431a of the cover 430 and is secured to the first support member 410, the second support member 420 between the cover 430 and the first support member 410 may be moved in the up-and-down direction about the first fastening member 451 within the first length l1 of the first through-hole 425a.

For example, a second fastening member 452 may be inserted into the second fixing member through-hole 431b of the cover 430, pass through the second through-hole 425b of the second support member 420, and be secured to the first support member 410. Since the second fastening member 452 passes through the second through-hole 425b of the second support member 420 while being inserted into the second fixing member through-hole 431b of the cover 430 and is secured to the first support member 410, the second support member 420 between the cover 430 and the first support member 410 may be moved in the up-and-down direction around the second fastening member 452 within the first length l1 of the second through-hole 425b.

The support device 400 may include a friction member 440 disposed between the first support member 410 and the second support member 420. The friction member 440 may be disposed between the front surface of the first support member 410 and the rear surface of the second support member 420. The friction member 440 may be configured to increase a frictional force between the first support member 410 and the second support member 420. The friction member 440 may be provided in an approximately plate shape. The friction member 440 may include a round plate protruding forward. The friction member 440 may be secured to the first support member 410 by the fixing member 450. The friction member 440 may be secured to the front surface of the first support member 410 by the fixing member 450. The friction member 440 may be configured to be secured to the front surface of the first support member 410 to increase a frictional force with the second support member 420. The friction member 440 may be configured to be secured in front of the first support member 410, and the second support member 420 may be configured to be movable in the up-and-down direction while in contact with the friction member 440.

The friction member 440 may include an opening 442 through which the fixing member 450 may pass. The opening 442 of the friction member 440 may be provided corresponding to the through-hole 425 of the second support member 420. A plurality of the openings 442 may be provided, and openings 442 may include a first opening 442a corresponding to the first through-hole 425a. The openings 442 may include a second opening 442b corresponding to the second through-hole 425b. The first fastening member 451 and the second fastening member 452 may pass through the first opening 442a and the second opening 442b, respectively, and be secured to the first support member 410. The first opening 442a and the second opening 442b may be formed smaller than the first through-hole 425a and the second through-hole 425b, respectively. The first opening 442a and the second opening 442b may be provided corresponding to a fastening member fixing portion 413, which will be described below.

The first support member 410 may include the fastening member fixing portion 413 to which the fixing member 450 is arranged to be fixed. The fastening member fixing portion 413 may be arranged on a front side of the first support member 410. The fastening member fixing portion 413 may be arranged at a front surface of the first support member 410. The fastening member fixing portion 413 may be provided for the fixing member 450 to be inserted and fixed. According to some embodiments, the fastening member fixing portion 413 may be a hole, but embodiments of the present disclosure are not limited thereto.

The fastening member fixing portion 413 may include a first fastening member fixing portion 413a to which the first fastening member 451 may be fixed. The fastening member fixing portion 413 may include a second fastening member fixing portion 413b to which the second fastening member 452 may be fixed.

The first opening 442a of the friction member 440 may be provided corresponding to the first fastening member fixing portion 413a. The second opening 442b of the friction member 440 may be provided corresponding to the second fastening member fixing portion 413b. The first fastening member 451 may pass through the first opening 442a of the friction member 440 and be secured to the first fastening member fixing portion 413a of the first support member 410. The second fastening member 452 may pass through the second opening 442b of the friction member 440 and be secured to the second fastening member fixing portion 413b of the first support member 410.

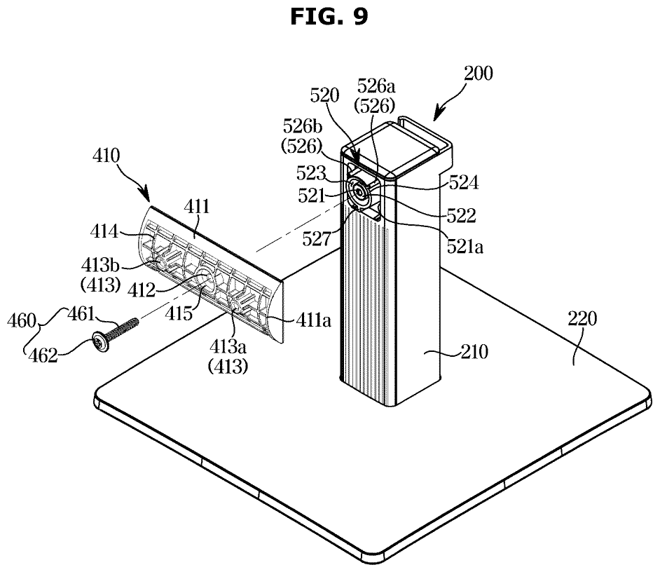

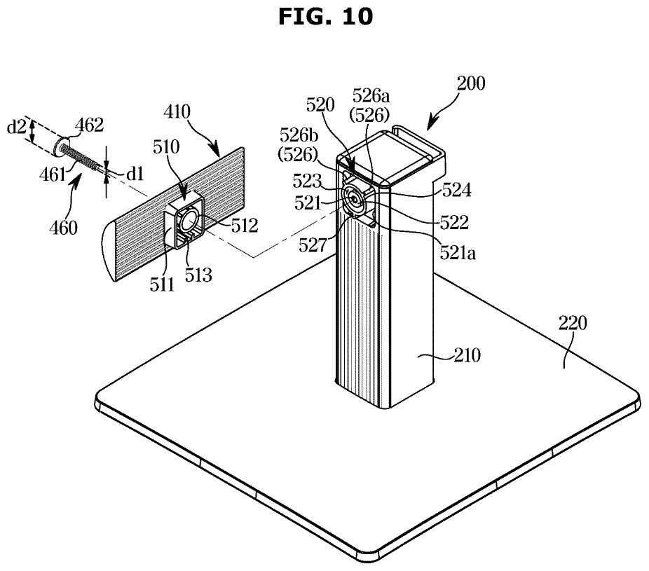

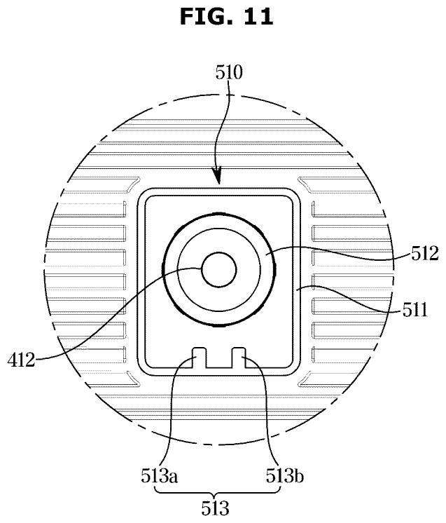

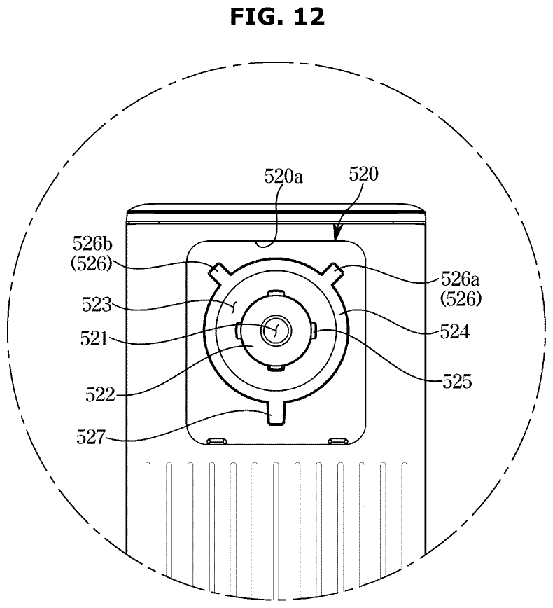

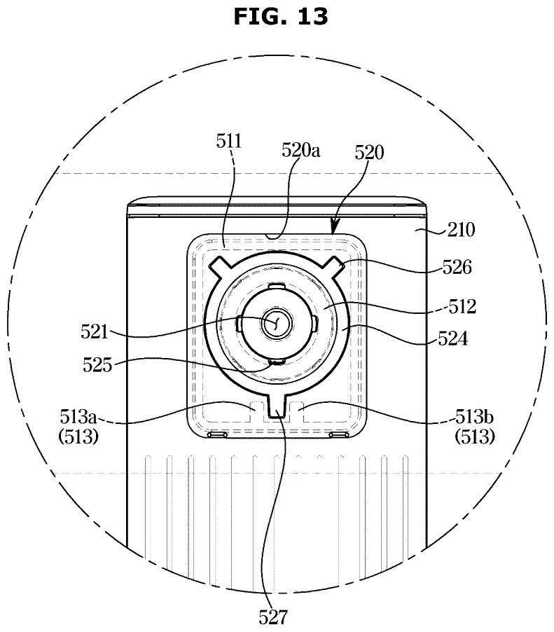

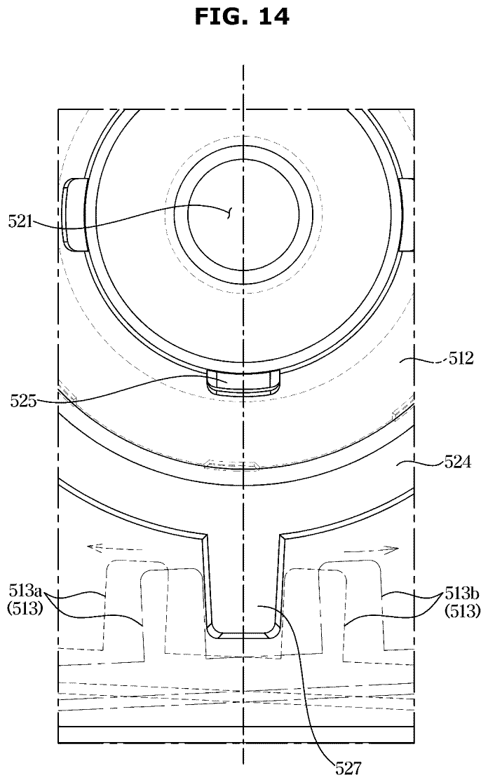

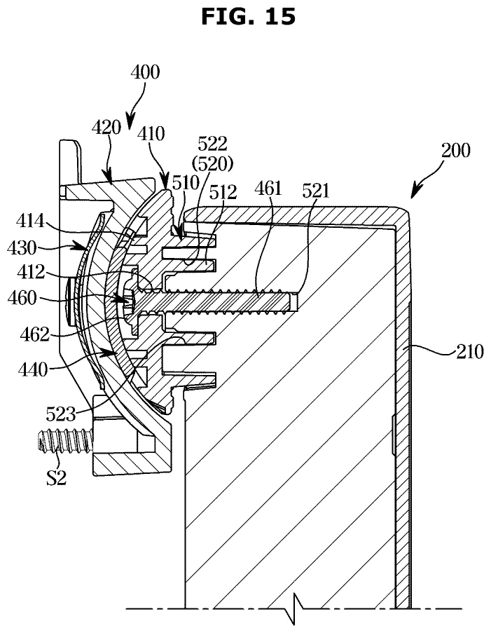

FIG. 9 is a view illustrating an exploded state of some configurations of the support device shown in FIG. 7. FIG. 10 is a view illustrating an exploded state of some configurations of the support device shown in FIG. 9, viewed from another direction. FIG. 11 is a view illustrating a portion of the first support member of the support device according to an embodiment. FIG. 12 is a view illustrating a portion of the stand coupled to the first support member according to an embodiment. FIG. 13 is a view illustrating a coupled state of the support device and the stand according to an embodiment. FIG. 14 is a view illustrating a rotational state of the first support member with respect to the stand according to an embodiment. FIG. 15 is a cross-sectional view taken along a line B-B′ of FIG. 5, illustrating a cross-section of some configurations of the stand and the support device according to an embodiment. Hereinafter, description of portions that are redundant with the description above may not be repeated.

As shown in FIGS. 9 to 15, the first support member 410 of the support device 400 may be rotatably coupled to the stand 200.

The first support member 410 may include the first support member body 411. The first support member 410 may include the center hole 412 provided for fastening of the fastening shaft 460 at its center. The first support member body 411 may include the center hole 412 formed to allow the fastening shaft 460 to pass therethrough.

The first support member 410 may include a fastening shaft coupling portion 415 for coupling of the fastening shaft 460. The fastening shaft coupling portion 415 may be formed on the front side of the first support member 410. The center hole 412 may be provided in the center of the fastening shaft coupling portion 415. The fastening shaft 460 may pass through and be coupled to the center hole 412 of the fastening shaft coupling portion 415. The fastening shaft coupling portion 415 may be arranged in the first support member body 411. The fastening shaft coupling portion 415 may be arranged on the front surface of the first support member body 411. The fastening shaft coupling portion 415 may be provided recessed rearwardly to allow the fastening shaft 460 to pass through and be coupled to the first support member 410. The fastening shaft coupling portion 415 may be formed recessed rearwardly from the round portion 411a of the first support member body 411. The fastening shaft coupling portion 415 may be formed in a shape corresponding to a head portion 462 of the fastening shaft 460, which will be described below.

The fastening member fixing portion 413 for fixing of the fixing member 450 may be provided on the front surface of the first support member 410. The fastening member fixing portion 413 may include the first fastening member fixing portion 413a provided on one side of the first support member 410 and the second fastening member fixing portion 413b provided on the other side of the first support member 410. The first fastening member fixing portion 413a and the second fastening member fixing portion 413b may be arranged to be spaced apart at a certain interval on both sides with respect to the center hole 412.

A bead 414 may be provided on the front surface of the first support member 410. The bead 414 may be provided on the front surface of the first support member body 411. The bead 414 may be formed extending in the up-and-down direction and/or a left-to-right direction of the first support member 410. The bead 414 may be formed extending in the up-and-down direction and/or the left-to-right direction of the first support member body 411. The bead 414 may be injection molded using a resin material. The bead 414 may be configured to increase the rigidity of the first support member 410, which is injection molded with a resin material.

The fastening shaft 460 may be configured to couple the first support member 410 to the stand 200. The fastening shaft 460 may pass through the center hole 412 of the first support member 410 and be secured to the stand 200. The fastening shaft 460 may pass through the center hole 412 of the first support member 410, and may be configured to rotatably couple the first support member 410 to the stand 200.

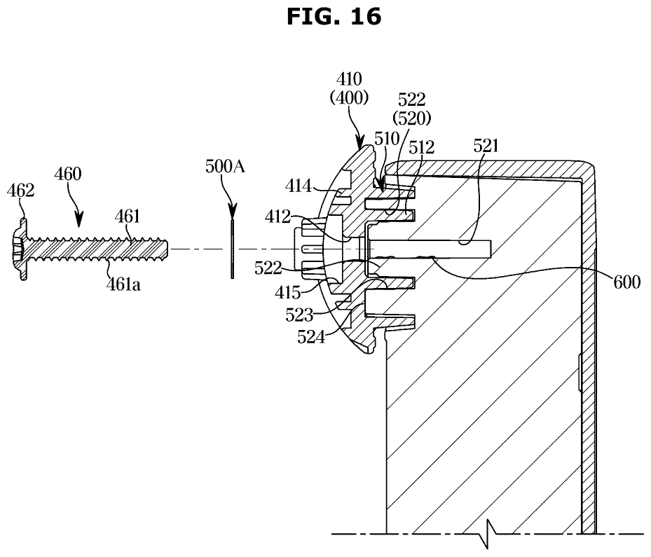

The fastening shaft 460 may include a body portion 461 and a head portion 462 extending from the body portion 461. The fastening shaft 460 may include the body portion 461 having threads 461a (see FIG. 16) formed on an outer circumferential surface thereof. For example, the body portion 461 may be provided with a first diameter d1. The fastening shaft 460 may include the head portion 462 having a larger diameter than a diameter of the body portion 461. For example, the head portion 462 may be provided with a second diameter d2. The first diameter d1 may be formed smaller than the second diameter d2.

The body portion 461 of the fastening shaft 460 may pass through the center hole 412 of the first support member 410 and be secured to the stand 200. The fastening shaft 460 may couple the first support member 410 to the stand 200 by the body portion 461 passing through the center hole 412 of the first support member 410 and being screw-coupled to the stand 200.

The first support member 410 may be rotatably coupled to the stand 200 about the fastening shaft 460.

The first support member 410 may include a rotation guide 510. The rotation guide 510 may be configured to rotate the first support member 410 relative to the stand 200. The rotation guide 510 may be arranged on a rear surface of the first support member 410. The rotation guide 510 may be arranged at a center of the rear surface of the first support member 410. The rotation guide 510 may be arranged at a center of the rear surface of the first support member body 411. The rotation guide 510 may be arranged adjacent to the center hole 412 such that the center hole 412 becomes a center of rotation.

The rotation guide 510 may include a rotation rib 512 formed around the center hole 412. The rotation rib 512 may be formed in a circular shape. The rotation rib 512 may be formed protruding rearwardly from the first support member 410. The rotation rib 512 may be configured to guide rotation of the first support member 410 about the fastening shaft 460 passing through the center hole 412. The rotation rib 512 may be configured to guide the rotation of the first support member 410.

The rotation guide 510 may include a rotation guide body 511 spaced apart and formed around an outer circumference of the rotation rib 512. The rotation guide body 511 may be formed in an approximately square shape. The rotation guide body 511 may be formed protruding rearwardly from the first support member 410. The rotation guide body 511 may be configured to couple the first support member 410 to the stand 200. The rotation guide body 511 may be configured to be insertable into a rotation guide groove 520a of the stand 200, which will be described below.

The rotation guide 510 may include a stopper 513 configured to limit a rotation angle of the first support member 410. The rotation guide 510 may include the stopper 513 for limiting the rotation angle of the first support member 410 upon rotation of the first support member 410. The stopper 513 may be arranged on the rotation guide body 511. The stopper 513 may be configured to protrude upwardly from a lower portion of the rotation guide body 511. The stopper 513 may include a first stopper 513a arranged on the lower portion of the rotation guide body 511. The stopper 513 may include a second stopper 513b arranged on the lower portion of the rotation guide body 511. The second stopper 513b may be located to be spaced apart from the first stopper 513a. The stopper 513 may be configured to allow an angle adjustment rib 527, which will be described below, to be caught. For example, the angle adjustment rib 527 may be positioned between the first stopper 513a and the second stopper 513b, such that rotation in one direction may be limited by the first stopper 513a, and rotation in the other direction may be limited by the second stopper 513b.

The stand 200 may include a rotation guide coupling portion 520 to which the rotation guide 510 of the first support member 410 is coupled. The rotation guide coupling portion 520 may be arranged on the stand leg 210. The rotation guide coupling portion 520 may be arranged on at least a portion of an upper side of the stand leg 210. The rotation guide coupling portion 520 may be provided corresponding to the rotation guide 510 of the first support member 410 for coupling.

The rotation guide coupling portion 520 may include the rotation guide groove 520a into which the rotation guide body 511 is insertable. The rotation guide groove 520a may be arranged on at least a portion of the stand 200. The rotation guide groove 520a may be arranged on at least a portion of the stand leg 210. The rotation guide groove 520a may be arranged on an upper portion of the stand leg 210. The rotation guide groove 520a may be provided in a shape corresponding to the rotation guide body 511, such that the first support member 410 may be coupled to the stand 200 by insertion of the rotation guide body 511. The first support member 410 may be coupled to the stand 200 by inserting the rotation guide body 511 into the rotation guide groove 520a.

The rotation guide coupling portion 520 may include a rotation shaft groove portion 522. The rotation shaft groove portion 522 may be configured to form a rotation shaft groove 521 in which the fastening shaft 460 is secured. The rotation shaft groove 521 may be configured to allow the body portion 461 of the fastening shaft 460 to be screw-coupled. The rotation shaft groove 521 may be configured to allow the body portion 461 of the fastening shaft 460 to be inserted. The rotation shaft groove 521 may be configured to allow the body portion 461 of the fastening shaft 460 to be screw-coupled. The rotation shaft groove 521 may be formed in a groove shape into which the body portion 461 of the fastening shaft 460 may be inserted. The fastening shaft 460 may include a tapping screw. The rotation shaft groove 521 may be provided such that the body portion 461 of the fastening shaft 460 may be inserted by self-drilling. The rotation shaft groove 521 may be formed with a smaller diameter than a diameter of the body portion 461 of the fastening shaft 460.

The rotation guide coupling portion 520 may include a rotation rib groove portion 524. The rotation rib groove portion 524 may be configured to form a rotation rib groove 523 in which the rotation rib 512 is inserted. The rotation rib groove 523 may be configured to allow the rotation rib 512 to be inserted. The rotation rib groove 523 may be provided to correspond to the rotation rib 512 for coupling. The rotation rib groove 523 may be formed in a circular shape for insertion of the rotation rib 512. The rotation rib 512 may be inserted into the rotation rib groove 523 and rotatably coupled thereto.

The rotation guide coupling portion 520 may include an anti-eccentricity portion 525. The anti-eccentricity portion 525 may be configured to prevent the rotation rib 512 from becoming eccentric when the rotation rib 512 is coupled to the rotation rib groove 523. The anti-eccentricity portion 525 may be arranged on an outer circumferential surface of the rotation shaft groove portion 522 forming one surface of the rotation rib groove 523. The anti-eccentricity portions 525 may be provided in a plurality on the outer circumferential surface of the rotation shaft groove portion 522. The plurality of anti-eccentricity portions 525 may be arranged spaced apart at regular intervals on the outer circumferential surface of the rotation shaft groove portion 522. Four anti-eccentricity portions 525 may be disposed on upper, lower, left, and right sides of the rotation shaft groove portion 522, respectively. The anti-eccentricity portion 525 may be configured such that the rotation rib 512 inserted into the rotation rib groove 523 may be located at a center thereof. The anti-eccentricity portion 525 may be configured to prevent the rotation rib 512 coupled to the rotation rib groove 523 from being eccentrically coupled by being positioned a certain distance apart from the rotation rib groove 523.

The rotation guide coupling portion 520 may include a position decision protrusion 526. The position decision protrusion 526 may be configured to confirm a coupling position of the first support member 410 when the first support member 410 is coupled to the stand 200. The position decision protrusion 526 may be arranged on the rotation rib groove portion 524. The position decision protrusion 526 may be formed protruding outwardly from an upper side of the rotation rib groove portion 524. The position decision protrusion 526 may be disposed on one upper side and the other upper side of the rotation rib groove portion 524. Two position decision protrusions 526 may be arranged to be spaced apart from each other on one side and the other side of the rotation rib groove portion 524. The position decision protrusion 526 may include a first position decision protrusion 256a disposed on one upper side of the rotation rib groove portion 524. The position decision protrusion 526 may include a second position decision protrusion 256b disposed on the other upper side of the rotation rib groove portion 524. In the present embodiment, two position decision protrusions are shown formed on the rotation rib groove portion as an example, but are not limited thereto. For example, the position decision protrusion may be configured to confirm the coupling position of the rotation guide of the first support member and the rotation guide coupling portion of the stand.

The rotation guide coupling portion 520 may include the angle adjustment rib 527. The angle adjustment rib 527 may be arranged on a lower side of the rotation rib groove portion 524. The angle adjustment rib 527 may be configured to protrude downwardly from the lower side of the rotation rib groove portion 524. The angle adjustment rib 527 may be configured to be limited in rotation by the stopper 513 of the rotation guide 510. For example, the angle adjustment rib 527 may be positioned between the first stopper 513a and the second stopper 513b. For example, the angle adjustment rib 527 may be positioned between the first stopper 513a and the second stopper 513b, such that rotation in one direction is limited by being caught by the first stopper 513a. For example, the angle adjustment rib 527 may be positioned between the first stopper 513a and the second stopper 513b, such that rotation in a direction opposite to the one direction may be limited by being caught by the second stopper 513b.

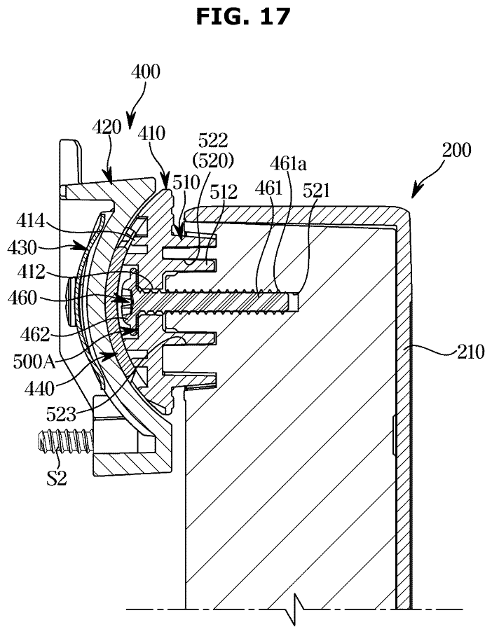

FIG. 16 is a view illustrating a state in which the first support member is coupled to the stand according to an embodiment. FIG. 17 is a cross-sectional view illustrating the support device coupled to the stand according to an embodiment. Hereinafter, description of portions that are redundant with the description above may not be repeated.

Referring to FIGS. 16 and 17, a method of coupling the support device 400 to the stand 200 via the fastening shaft 460 will be described.

The first support member 410 of the support device 400 may be coupled to the stand 200 by the fastening shaft 460.

The rotation guide coupling portion 520 may be arranged on the stand leg 210 of the stand 200 so that the first support member 410 may be rotatably coupled. The rotation guide coupling portion 520 may be formed on the stand leg 210, which may be injection molded with a resin material.

For example, the stand leg 210 may be provided with the rotation shaft groove 521 for coupling of the fastening shaft 460. For example, the stand leg 210 may be provided with the rotation rib groove portion 524 forming the rotation rib groove 523 for coupling of the rotation rib 512 of the first support member 410.

The first support member 410 may be coupled to the stand leg 210 by positioning the rotation guide 510 arranged on the rear surface of the first support member 410 to correspond to the rotation shaft groove 521 and the rotation rib groove 523 of the rotation guide coupling portion 520 of the stand leg 210, respectively, and inserting the rotation guide 510 into them.

A washer 500A may be coupled via the body portion 461 of the fastening shaft 460. The washer 500A may be disposed between the fastening shaft 460 and the first support member 410. The washer 500A may be configured to prevent wear, noise, loosening of a screw, etc., due to friction between the head portion 462 of the fastening shaft 460 and the first support member 410. The washer 500A may include a polyoxymethylene (POM) washer. The POM washer may have inherent properties of POM, such as lubricity, durability, fatigue resistance, creep resistance, and strong resistance to friction and wear, and thus may prevent wear, noise, screw loosening of a screw, etc., due to friction between the head portion 462 of the fastening shaft 460 and the first support member 410.

The body portion 461 of the fastening shaft 460 may pass through the fastening shaft coupling portion 415 and the center hole 412 of the first support member 410 and be screw-coupled to the rotation shaft groove 521.

Before screw-coupling the fastening shaft 460 to the rotation shaft groove 521 of the stand leg 210, the rotation shaft groove 521 of the stand leg 210 may be coated with a liquid adhesive 600.

With the first support member 410 inserted and coupled to the rotation guide coupling portion 520 of the stand leg 210, the fastening shaft 460 with the washer 500A coupled thereto may be screw-coupled to the rotation shaft groove 521 to which the liquid adhesive 600 has been applied.

The body portion 461 of the fastening shaft 460 may pass through the center hole 412 of the first support member 410 and be inserted into the rotation shaft groove 521. The head portion 462 of the fastening shaft 460 may be configured to be supported by the washer 500A on the fastening shaft coupling portion 415 of the first support member 410.

The body portion 461 of the fastening shaft 460 may be inserted and coupled to the rotation shaft groove 521 while forming a screw shape in the rotation shaft groove 521 by screw-coupling the threads 461a formed on the body portion 461 of the fastening shaft 460 to the rotation shaft groove 521.

The display apparatus 1 according to an embodiment of the present disclosure may include the display 100 including the display panel 110 and the chassis 300 supporting the display panel 110; the stand 200 configured to support the display 100; and the support device 400 arranged between the display 100 and the stand 200, wherein the support device 400 comprises a first support member 410 in which the center hole 412 is formed; the fastening shaft 460 including the body portion 461 having the thread 461a formed on an outer circumferential surface of the body portion 461, and the head portion 462 having a larger diameter than a diameter of the body portion 461, the fastening shaft being configured to couple the first support member 410 to the stand 200 by the body portion 461 extending through the center hole 412 and screw-coupling the body portion 461 to the stand 200; the second support member 420 secured to the chassis 300 and coupled to the first support member 410; wherein the first support member 410 is rotatable with respect to the stand 200 about the fastening shaft 460, and the second support member 420 is movable in an up-and-down direction with respect to the first support member 410. According to the embodiment of the present disclosure, the display panel may be leveled by including the stand with an improved structure.

The first support member 410 and the second support member 420 may be formed by injection molding. According to the embodiment of the present disclosure, the stand may be formed by injection molding using a resin material. Such a configuration may cause the manufacturing and material costs of the display apparatus to be relatively reduced.

The support device 400 may further include the cover 430 arranged on one side of the second support member 420 to support the second support member 420, and the fixing member 450 configured to secure the cover 430 to the first support member 410.

The support device 400 may include the friction member 440 arranged between the first support member 410 and the second support member 420.

The first support member 410 may include the rotation guide 510 configured to be rotatable with respect to the stand 200, and the rotation guide 510 may include the rotation rib 512 and the stopper 513, the stopper 513 configured to limit a rotation angle (e.g., of the first support member 410).

The stopper 513 may include the first stopper 513a disposed on one side and the second stopper 513b disposed to be spaced apart from the first stopper 513a.

The stand 200 may include the rotation guide coupling portion 520 corresponding to the rotation guide 510, and the rotation guide coupling portion 520 may include the rotation shaft groove portion 522 configured to form the rotation shaft groove 521 to which the fastening shaft 460 is coupled, the rotation rib groove portion 524 configured to form the rotation rib groove 523 into which the rotation rib 512 is inserted, and the angle adjustment rib 527 formed to protrude outwardly from the rotation rib groove portion 524 to limit the rotation angle by the stopper 513.

The rotation guide coupling portion 520 may further include the anti-eccentricity portion 525 formed to protrude from an outer circumference of the rotation rib groove portion 524 to prevent eccentricity of the rotation rib 512.

The rotation guide coupling portion 520 may further include the position decision protrusion 526 formed to protrude from an outer circumference of the rotation rib groove portion 524 for coupling with the rotation guide 510.

The angle adjustment rib 527 may be positioned between the first stopper 513a and the second stopper 513b.

The support device 400 may further include the washer 500A arranged between the fastening shaft 460 and the first support member 410.

The stand 200 may include the stand leg 210 on which the rotation guide coupling portion 520 is provided for coupling of the support device 400; the stand base 220 arranged on one side of the stand body to support the stand leg 210.

The display 100 may further include the rear cover 120 covering a rear side of the chassis 300, and the rear cover 120 may include the first through-hole 122 and the second through-hole 123 that are configured receive a portion of the second support member 420.

The second support member 420 may include the first insertion protrusion 241 and the second insertion protrusion 242 configured to protrude upwardly and be inserted into the first through-hole 122 and the second through-hole 123.

The chassis may be formed by injection molding.

The display apparatus 1 according to an embodiment of the present disclosure, being detachably couplable to the stand 200, may include the display panel 110; the display 100 supporting the display panel 110; the stand 200 detachably couplable to the display 100; and the support device 400 arranged between the display 100 and the stand 200; wherein the support device 400 includes the first support member 410 secured to the stand 200 via a fastening shaft 460 and rotatable about the fastening shaft 460; the second support member 420 configured to contact the first support member 410 to generate a frictional force and fixed to the display 100 to allow the display 100 to be movable in an up-and-down direction; and the fixing member 450 configured to fix the cover 430, which is arranged on one side of the second support member to support the second support member 420, to the first support member 410.

The first support member 410 and the second support member 420 may be formed by injection molding.

The support device 400 may further include the friction member 440 configured to contact the other surface of the second support member 420, and the friction member 440 may be arranged between the second support member 420 and the first support member 410.

The first support member 410 may include the rotation guide 510 configured to be rotatable with respect to the stand 200, and the rotation guide 510 may include the rotation rib 512 and the stopper 513, the stopper 513 configured to limit a rotation angle (e.g., of the first support member 410).

The stand 200 may include the rotation guide coupling portion 520 corresponding to the rotation guide 510, and the rotation guide coupling portion 520 may include the rotation shaft groove portion 522 configured to form the rotation shaft groove 521 to which the fastening shaft 460 is coupled, the rotation rib groove portion 524 configured to form the rotation rib groove 523 into which the rotation rib 512 is inserted, and the angle adjustment rib 527 formed to protrude outwardly from the rotation rib groove portion 524 to limit the rotation angle by the stopper 513.

Although non-limiting example embodiments have been described above with reference to the accompanying drawings, the present disclosure is not limited to the example embodiments described above, and it will be apparent to those skilled in the art that various changes and modifications can be made without departing from the spirit and scope of the present disclosure.

What is claimed is:

1. A display apparatus comprising:
a display comprising a display panel and a chassis supporting the display panel;
a stand configured to support the display; and
a support device between the display and the stand,
wherein the support device comprises:
a first support member including a center hole;
a fastening shaft comprising a body portion comprising a thread on an outer circumferential surface of the body portion, and the fastening shaft further comprising a head portion having a larger diameter than a diameter of the body portion, wherein the fastening shaft is configured to connect the first support member to the stand by the body portion extending through the center hole and screw-connecting to the stand; and
a second support member connected to the chassis and the first support member,
wherein the first support member is configured to rotate with respect to the stand about the fastening shaft, and
wherein the second support member is configured to move in an up-and-down direction with respect to the first support member.

2. The display apparatus of claim 1, wherein
the first support member and the second support member are formed by injection molding.

3. The display apparatus of claim 1, wherein the support device further comprises:
a cover on one side of the second support member, the cover configured to support the second support member, and
a fixing member configured to connect the cover to the first support member.

4. The display apparatus of claim 1, wherein the support device further comprises a friction member between the first support member and the second support member.

5. The display apparatus of claim 1, wherein
the first support member comprises a rotation guide configured to be rotatable with respect to the stand, and
the rotation guide comprises a rotation rib and at least one stopper, the at least one stopper configured to limit a rotation angle of the first support member.

6. The display apparatus of claim 5, wherein the at least one stopper comprises a plurality of stoppers, the plurality of stoppers comprising:
a first stopper, and
a second stopper spaced apart from the first stopper.

7. The display apparatus of claim 6, wherein
the stand comprises a rotation guide coupling portion corresponding to the rotation guide, and
the rotation guide coupling portion comprises:
a rotation shaft groove portion configured to form a rotation shaft groove to which the fastening shaft is coupled,
a rotation rib groove portion comprising a rotation rib groove, the rotation rib groove configured to receive the rotation rib, and
an angle adjustment rib protruding outwardly from the rotation rib groove portion, the angle adjustment rib configured to limit the rotation angle by contacting the first stopper or the second stopper.

8. The display apparatus of claim 7, wherein
the rotation guide coupling portion further comprises an anti-eccentricity portion protruding from an outer circumference of the rotation rib groove portion, the anti-eccentricity portion configured to prevent eccentricity of the rotation rib.

9. The display apparatus of claim 7, wherein
the rotation guide coupling portion further comprises a position decision protrusion protruding from an outer circumference of the rotation rib groove portion, the position decision protrusion configured to connect to the rotation guide.

10. The display apparatus of claim 7, wherein
the angle adjustment rib is between the first stopper and the second stopper.

11. The display apparatus of claim 1, wherein
the support device further comprises a washer between the fastening shaft and the first support member.

12. The display apparatus of claim 7, wherein the stand comprises:
a stand leg, wherein the rotation guide coupling portion is on the stand leg, and the rotation guide coupling portion is configured to couple the support device to the stand leg, and
a stand base on one side of a stand body, the stand base configured to support the stand leg.

13. The display apparatus of claim 12, wherein
the display further comprises a rear cover on a rear side of the chassis, and
the rear cover comprises a through-hole that is configured receive a portion of the second support member.

14. The display apparatus of claim 13, wherein
the second support member comprises an insertion protrusion that protrudes upwardly, wherein the insertion protrusion is configured to be inserted into the through-hole.

15. The display apparatus of claim 1, wherein
the chassis is formed by injection molding.

16. A system comprising:
a display comprising a display panel and a chassis supporting the display panel;
a stand configured to support the display; and
a support device configured to be between the display and the stand,
wherein the support device comprises:
a first support member including a center hole;
a fastening shaft configured to connect the first support member to the stand while the fastening shaft extends through the center hole; and
a second support member configured to be connected to the chassis and the first support member,
wherein the first support member is configured to rotate with respect to the stand about the fastening shaft, and
wherein the second support member is configured to move in an up-and-down direction with respect to the first support member.

17. The system of claim 16, wherein
the first support member and the second support member are formed by injection molding.

18. The system of claim 16, wherein the support device further comprises:
a cover on one side of the second support member, the cover configured to support the second support member, and
a fixing member configured to connect the cover to the first support member.

19. The system of claim 16, wherein the support device further comprises a friction member between the first support member and the second support member.

20. A support device of a display apparatus, the support device comprising:
a first support member including a center hole;
a fastening shaft comprising a body portion comprising a thread on an outer circumferential surface of the body portion, and the fastening shaft further comprising a head having a larger diameter than a diameter of the body portion, wherein the fastening shaft is configured to connect the first support member to a stand of the display apparatus by the body portion extending through the center hole and screw-connecting to the stand; and
a second support member configured to be connected to the first support member and a display of the display apparatus,
wherein the first support member is configured to rotate with respect to the stand about the fastening shaft, and
wherein the second support member is configured to move in an up-and-down direction with respect to the first support member.
